(19) United States
(12) Patent Application Publication
(10) Pub. No.: US 2009/0022997 A1
(43) Pub. Date: Jan. 22, 2009

(54) Transparent Conductive Oxide Films Having Enhanced Electron Concentration/Mobility, and Method of Making Same

(76) Inventors: David A. Russo, Audubon, PA (US); Jeffery L. Stricker, Narberth, PA (US); Ryan C. Smith, Collegeville, PA (US); Thomas D. Culp, La Crosse, WI (US); Roman Y. Korotkov, King of Prussia, PA (US); Gary S. Silverman, Chadds Ford, PA (US)

Correspondence Address: ARKEMA INC.;PATENT DEPARTMENT - 26TH FLOOR, 2000 MARKET STREET, PHILADELPHIA, PA, 19103-3222, US

(21) Appl. No.: 10/583,747

(22) PCT Filed: Dec. 30, 2004
(86) PCT No.: PCT/US04/43835

§ 371 Date: Sep. 22, 2008

Related U.S. Application Data
(60) Provisional application No. 60/538,640, filed on Jan. 23, 2004.

(51) Int. Cl. B32B 9/00; C23C 16/00; C23C 16/40

(52) U.S. Cl. 428/432; 428/702; 428/701; 428/697; 427/248.1; 427/255.32; 427/255.31

(57) ABSTRACT

A variety of new n-type TCO films including films with dopants having ionic sizes that approximate those of the metal oxide host material, films with stabilized rutile MO₂, and films with AₓMO_{y}. The films are deposited by APCVD.

### BACKGROUND OF THE INVENTION

1. Field of the Invention

This invention relates to transparent conductive oxide (TCO) films or coatings, and in particular to new multi-cation, thin film, n-type TCO films in which optimal electron concentration and mobility is achieved by selecting dopants having ionic sizes that approximate those of the oxide host material, and therefore are essentially non-disruptive to the host crystal lattice, thereby reducing electron scattering and increasing film conductivity.

The invention also relates to a method of forming TCO films or coatings by atmospheric pressure chemical vapor deposition (APCVD) of soluble solutions with a controlled crystallite size, quality and orientation to yield new n-type TCOs with enhanced electron concentration and mobility, and minimal defects.

The improved TCO films of the invention may be used in a variety of applications where performance of the films is affected by electron concentration and/or electron mobility, including solar control films in applications requiring a low plasma wavelength, and ohmic contact films in applications where low-resistivity is critical, such as in wide band gap semiconductor devices.

2. Description of Related Art

One of the applications of the TCO films or coatings of the invention is for use as solar control coatings, such as might be used on window glass. In general, it is desirable for such coatings to maximize transmittance of visible light while reflecting most infrared and near infrared (NIR) light. The amount of NIR light reflected depends on the “plasma wavelength,” which in a TCO coating or film is inversely proportional to the electron concentration in the coating. On the other hand, the transmittance of visible light by a TCO coating depends on electron mobility. In order to achieve an effective solar control coating, it is necessary to have a low plasma wavelength (or high plasma frequency), and high electron mobility. However, current thin film coating technologies permit only one of the two desired properties, electron concentration and electron mobility, to be optimized in a given film.

Much of the present research on thin film TCOs has focused on increasing conductivities, particularly with respect to Indium and/or Cadmium cation combinations. See, e.g., A. J. Freeman et al., MRS Bulletin, August 2000, pp. 45-51. However, even though In—Cd—O phases have some of the highest room temperature electrical conductivities measured for thin films (3500 S/cm), with mobilities as high as 200 cm²/Vs, electron concentrations were only 1×10²⁰ e/cm³, well below the typical 10²¹ for doped In₂O₃ films. On the other hand, some highly conductive In—Ga—Sn—O phases have conductivities as high as 3280 S/cm with measured electron concentrations of 8.6×10²⁰ e/cm³, but mobilities of only 24 cm²/Vs. Thus, in these prior art materials, either the electron concentration is too low to achieve an optimal plasma wavelength, or the electron mobility is too low to achieve optimal transmittance.

Most of the prior films were prepared using low pressure and plasma assisted chemical vapor deposition (CVD), and/or dc or rf sputtering techniques, as opposed to APCVD, as discussed above. Examples of currently used TCOs deposited by sputtering on glass include ZnO:Al, Cd₂SnO₄, Zn₂SnO₄, ZnSnO₃, ZrO₂, CeO₂, WO₃, and RuO₂. Examples of currently used TCOs which may be deposited by conventional low pressure CVD include ZnO:In (Al, F, Ga), SnO₂:F, TiN, and In₂O₃:Sn (ITO). A preferred commercial thin film TCO coating material, In₂O₃:Sn, has a plasma wavelength of 1 mm with an electron concentration of 10²¹ cm⁻³.

One approach to increasing the conductivity of TCO films by using APCVD, as opposed to conventional low pressure CVD or sputtering, is described in U.S. Pat. No. 6,524,647 (Varanesi et al.), which discloses APCVD of niobium doped tin oxide films. According to the Varanesi et al. patent, niobium is especially suited for replacing tin in the tin oxide lattice because it has a similar outer shell electron configuration and a comparable atomic number to that of tin. However, Varanesi et al. fails to optimize electrical properties because it fails to recognize that a key factor is actually the ionic size of the dopant, rather than atomic number or outer shell electron configuration.

In contrast, the present invention seeks to enable the ideal balance between electron concentrations, by selection of dopants according to the ionic size of the dopant relative to the oxide matrix, and appropriate control of the APCVD process used to deposit the doped oxides. None of the above-mentioned processes takes into account ionic size for the purpose of optimizing electron concentration and/or electron mobility.

### SUMMARY OF THE INVENTION

It is accordingly a first objective of the invention to overcome the disadvantages of the prior art by providing TCO films having improved electrical properties, and that can be produced in an efficient and cost-effective manner.

It is a second objective of the invention to provide TCOs having high visible transmission and improved NIR reflective properties.

It is a third objective of the invention to provide transparent conductive oxides having high conductivity and an optimal combination of electron concentration and electron mobility for a given application.

It is a fourth objective of the invention to provide a method of making transparent conductive oxides that permits optimization of electron concentration and electron mobility, in order to improve visible transmission and NIR reflective properties, and/or to provide films having low resistivity and high work function.

It is a fifth objective of the invention to provide a method of using APCVD to deposit TCO films or coatings having improved electrical or optical properties.

These objectives of the invention are accomplished, in accordance with the principles of a preferred embodiment of the invention, by a variety of new n-type TCO films in which the dopants have ionic sizes that approximate those of the metal oxide host material, and that therefore are essentially non-disruptive to the host crystal lattice, reducing electron scattering and increasing film conductivity.

These objectives are further achieved by using atmospheric pressure chemical vapor deposition to deposit soluble solutions having ionic sizes that approximate those of the metal oxide host material to be deposited. The resulting doped metal oxide films have higher conductivities, which in turn imparts better NIR reflective properties to the films than, for example, the current state of the art tin doped indium oxide.

According to a first preferred embodiment of the invention, a metal oxide host, is deposited on a substrate in conventional fashion, but the dopants are chosen to approximately match the ionic side of the host crystals. Suitable hosts, with ionic size given in parentheses, include Zn²⁺(0.74 Å)O, Sn⁴⁺(0.71 Å)O₂, Ge⁴⁺(0.53 Å)O₂, Zr⁴⁺(0.80 Å)O₂, Ti⁴⁺(0.68 Å)O₂, or Ga³⁺(0.62 Å)₂O₃, while suitable dopants according to the invention include ions such as Sn⁴⁺(0.71), Bi⁵⁺(0.74 Å), Ta⁵⁺(0.73 Å), Hf⁴⁺(0.80 Å), Mo⁶⁺(0.62 Å), Te⁶⁺(0.59 Å), Nb⁵⁺(0.70 Å) and the like, all of which have sizes that approximate those of the metal oxide host material. The enhanced conductivity is manifest by both an increase of electron concentration and mobility as measured by the Hall effect.

According to a second preferred embodiment of the invention, a rutile MO₂ layer is deposited on SnO₂ or other metal oxide capable of stabilizing the rutile MO₂ film and optimize near infrared (NIR) reflection in glass/SnO₂/MO₂ bilayers and glass/SnO₂/MO₂/SnO₂ sandwich structures. Suitable rutile MO₂ materials include but are not limited to M=Ti, V, Cr, Mo, Ru, or mixed alloys thereof.

According to a third preferred embodiment of the invention, SnₓM₁₋ₓO₂ films are deposited on a substrate, where the metal-semiconductor transition of MO₂ films is modified by alloying with SnO₂, thus optimizing the NIR reflection.

According to a fourth preferred embodiment of the invention, films such as but not limited to WO₃, MoₓO_{y}, AₓWO₃, and AₓMo₁₋ₓO_{y} are deposited on a substrate where A is H, Li, Na, and K, and x=0-2 and high enough to modify the plasma wavelength to optimize the NIR reflectance. The film properties may be enhanced by APCVD deposition of WO₃ or MoₓO_{y} on soda lime glass substrates with consecutive annealing/diffusion of Na, Li and K from the glass, and/or vapor phase incorporation/implantation of A into WO₃.

Electron concentrations ranging from 7-10×10²⁰e/cm³ are possible with the novel n-type TCO films deposited by the above-described processes, as well as electron mobilities of 50-150 cm²/vsec. In addition, these doped metal oxide films can be undercoated with one or more functional layers that can act as barrier layers to ion migration from the glass, anti-iridescent layers to reduce reflected color, and/or nucleation layers to alter the orientation of the TCO layer(s).

### DETAILED DESCRIPTION OF THE PREFERRED EMBODIMENTS

As will be apparent from the examples set forth below, this invention provides a variety of new n-type TCO films, each having an ideal balance between electron concentration and mobility, by selecting dopants that are essentially non-disruptive to the host crystal lattice, thereby reducing electron scattering and increasing film conductivity. According to the method of the invention, the films are deposited on heated substrates such as glass by APCVD of organometallic precursors combined with specific dopants and other additives such that the deposited films have a higher electron concentration. The higher electron concentration is due to the incorporation of dopant ions in the host oxide lattice that cause little or no disruption of the lattice parameters, thereby decreasing electron scattering and increasing conductivity.

In a first preferred embodiment of the invention, doped metal oxide films are prepared by APCVD on a suitable substrate, such as soda lime glass, the metal oxides having crystal lattice host sizes ranging from 0.60 Å to 0.80 Å. Therefore, according to the principles of the invention, the ionic sizes of the dopants are also chosen to be approximately within this range. For example, suitable metal oxide hosts include, but are not limited to, Zn²⁺(0.74 Å)O, Sn⁴⁺(0.71 Å)O₂, Ge⁴⁺(0.53 Å)O₂, Zr⁴⁺(0.80 Å)O₂, Ti⁴⁺(0.68 Å)O₂, and Ga³⁺(0.62 Å)₂O₃, the ionic sizes of which are set forth in the parentheses. Ideal dopants for these metal oxide hosts include ions such as Sn⁴⁺(0.71), Bi⁵⁺(0.74 Å), Ta⁵⁺(0.73 Å), Hf⁴⁺(0.80 Å), Mo⁶⁺(0.62 Å), Te⁶⁺(0.56 Å), Nb⁵⁺(0.70 Å) and the like, as well as combinations of any of the above-dopants.

Table 1 is a table illustrating the properties of MO₂ compounds with rutile structure manufactured according to the principles of the first preferred embodiment of the invention.

TABLE 1
MO₂ compound properties with rutile structure

| | | | V~10⁻²³ | N_{Site} (Sn) | N_{Site} (O) | % dopant | E_{G}, | Thermal | Plasma |
|---|---|---|---|---|---|---|---|---|---|
| MO₂ | a, Å | c, Å | cm⁻³ | ~10²², cm⁻³ | ~10²², cm⁻³ | (O)* | eV | Expansion | ~ₚ, ~m |
| SnO₂ | 4.738 | 3.187 | 7.115 | 2.8 | 5.6 | 3.57 | 3.8 | 0.02 | 1.3 |
| | | | | | | | | | (7~10²⁰ |
| | | | | | | | | | cm⁻³) |
| TiO₂ | 4.585 | 2.95 | 6.2 | 3.22 | 6.45 | 3.1 | 3.0 | 0.114 | |
| MnO₂ | 4.396 | 2.871 | 5.548 | 3.6 | 7.2 | 2.7 | Metal | 0.05 | |

*the required incorporation of a singly charged donor F, Cl, Br on O lattice site to obtain n = 2~1021, cm−3 with the plasma wavelength of 0.77 ~m.

In a second preferred embodiment of the invention, the principles of the invention are applied to hetero-epitaxial growth of APCVD-deposited doped and undoped rutile MO₂ structures, where M=Ti, V, Cr, Mo, Ru or mixed alloys thereof, on a SnO₂ or other metal oxide layer suitable for stabilizing the rutile MO₂ film and optimizing the near infrared reflection (NIR) in glass/SnO₂MO₂ bilayers and glass/SnO₂/MO₂/SnO₂ sandwich structures. Some of the MO₂ materials, such as CrO₂, MoO₂, RuO₂, have metallic conduction with high visible absorption. Others, such as TiO₂, are semiconductors with band gaps of 3.0 eV and high visible transparency. Still others, such as VO₂, have metal to semiconductor transitions at 340K. In all cases, however, the invention permits modification of the NIR reflectance of the coatings by depositing glass/SnO₂/MO₂ bilayers and glass/SnO2/MO₂/SnO₂ sandwich structures, where other metal oxides capable of stabilizing the rutile MO₂ layer may be substituted for SnO₂. Since the host materials crystallize in a rutile structure, as illustrated in FIG. 1, it is expected that the deposited MO₂ films will crystallize in a similar fashion to produce epitaxial like layers. Also, since lattice parameters are close to that of SnO₂ for most of these materials, only small stresses are expected in (001) planes. The third preferred embodiment of the invention involves a variation of the second preferred embodiment in which APCVD is used to grow SnₓM₁₋ₓO₂ ternary alloy system layers that modify the band gap parameters of SnO₂. By tuning the fraction of the transition metal, one can obtain the necessary high NIR reflection with high electron concentration.

Finally, in accordance with the principles of a fourth preferred embodiment of the invention, APCVD is used to grow oxide coatings having the form WO₃ (as well as oxides such as MoₓO_{y}) and AₓWO₃, (AₓMo₁₋ₓO_{y}), where A is H, Li, Na, and K, and x=0-2 and high enough to modify the plasma wavelength to optimize the NIR reflectance. In one embodiment, enhanced film properties are achieved by APCVD deposition of WO₃ or MoₓO_{y} films on soda lime glass substrates with consecutive annealing/diffusion of Na, Li and K from the glass, and/or vapor phase incorporation/implantation of A into WO₃.

Theoretical studies of AₓWO₃ indicate the possibility of a reflectance band shift towards the visible by increasing the fraction x of alkali metals in the ternary compound. According to a preferred embodiment of the invention, the plasma wavelength of these coatings is tuned to 0.7 mm by varying the content of alkali metals in the coatings on glass and other substrates. Note that the amount of A is significantly higher than that used in Li-doped WO₃ films prepared for their electrochromic properties, where alkali doping is typically less than a few percent. In addition, one can use Na (Li, K) diffusion from glass substrates in APCVD grown MO_{y} films to help promote formation of AₓMO₃. In addition, implantation or vapor deposition of films with A may be used in this embodiment.

A predictive example of the first preferred embodiment of the invention, in which the doped metal oxide is tantalum doped zinc oxide, follows:

### Predictive Example

A 2.2 mm thick glass substrate (soda lime silica), two inches square, is heated on a hot block to about 650° C. The substrate may be positioned about 25 mm under the center section of a vertical concentric tube coating nozzle. A carrier gas of dry oxygen flowing at a rate of 12.5 liters per minute (lpm) is then heated to about 160° C. and passed through a hot wall vertical vaporizer.

A liquid coating solution containing monobutyltin trichloride (MBTC) is fed to the vaporizer via a syringe pump at a volume flow designed to give a 0.5 mol % concentration in the gas composition. A second liquid coating solution of tetraethyl orthosilicate (TEOS) and triethyl phosphite (TEP) in a 1:1 mol ratio is fed to the vaporizer via a syringe pump at a volume flow designed to give a 0.5 mol % concentration in the gas composition.

The gas mixture is then allowed to impinge on the glass substrate for about 4 seconds to deposit a mixed oxide of tin and silicon about 80 nm thick with a refractive index of about 1.70. Immediately following, a second gas mixture composed of a diethylzinc tetraethylethylenediamine complex (DEED), a nitrogen carrier gas, tantalum (V) ethoxide, water vapor and air is caused to impinge on the metal oxide coated surface for about 30 seconds, resulting in a tantalum doped zinc oxide film of about 300 nm. The second gas mixture may be formed by mixing separate gas streams in a manifold just before the coating nozzle. The water vapor and air are introduced at the top of the nozzle to minimize premature reaction with the zinc and tantalum precursors. The DEED liquid is fed via a syringe pump to a second vaporizer through which a nitrogen carrier gas is flowing at 160° C. at about 10 lpm. The volume flow is preferably designed to give a 0.5 mole % concentration in the carrier gas.

Finally, the tantalum precursor is fed via a syringe pump to a third vaporizer through which a nitrogen carrier gas is flowing at 180° C. at about 10 lpm. The volume flow is designed to give a 0.1 mole % concentration in the carrier gas. Water is fed via syringe pump into a vaporizer through which an air carrier gas was flowing at about 10 lpm. The vapor concentration is about 3 moles per mole of zinc precursor.

The bilayer film stack made by the above method is predicted to have essentially no reflected color, a visible transmission greater than 70%, an electron concentration in the range of 7-10×10²⁰e/cm³ and a mobility above 50 cm²/v-sec as measured by the Hall effect.

In a similar manner, hafnium doped zirconium dioxide, molybdenum doped gallium oxide and bismuth/tantalum doped tin oxide films could be prepared. In some cases, the precursors would be placed in heated bubblers and the carrier gas would pass through a molten liquid. These examples are only illustrative of the current invention and one skilled in the art will realize that minor variations outside these embodiments do not depart from the spirit and scope of this invention.

Having thus described various preferred embodiments of the invention in sufficient detail to enable those skilled in the art to make and use the invention, it will nevertheless be appreciated that numerous variations and modifications of the illustrated embodiment may be made without departing from the spirit of the invention. For example, other dopant and host combinations not mentioned herein could be used. Binary and tertiary dopant combinations could be found which might yield films with even higher conductivities. Other undercoat films could be used which have better barrier, anti-reflection or nucleating layer properties than the combinations described herein. Anti-reflection layers could be placed on top of the doped metal oxide layer. Dopants could be incorporated into the host oxide layer in a gradient fashion; one dopant gradually decreasing while the other gradually increases in a continuum or step fashion. Separate dopant layers could be combined. The dopants described herein all are intended to replace some of the metal host ions. The enhanced effect might also be accomplished by combining dopants of this invention with dopants such as fluorine that substitute for some of the oxygen atoms in the host matrix.

As a result, it is intended that the invention not be limited by the above description, but that it be defined solely in accordance with the appended claims.

What is claimed is:

1. A transparent conductive oxide film comprising a doped metal oxide, wherein the ionic size of at least one dopant in the doped metal oxide approximates the size of the host ions in an oxide lattice in the doped metal oxide.

2. The transparent conductive oxide film as claimed in claim 1, wherein the ionic size of said dopant is between approximately 0.6 Å and 0.8 Å.

3. The transparent conductive oxide film as claimed in claim 2, wherein said metal oxide is selected from the group consisting of Zn²⁺O, Sn⁴⁺O₂, Ge⁴⁺O₂, Zr⁴⁺O₂, Ti⁴⁺O₂, Ga³⁺₂O₃, and mixtures thereof, and wherein said at least one dopant is selected from the group consisting of Sn⁴⁺, Bi⁵⁺, Ta⁵⁺, Hf⁴⁺, Mo⁶⁺, Te⁶⁺, Nb⁵⁺, and mixtures thereof.

4. A coated substrate comprising a substrate having directly coated thereon the transparent conductive oxide of claim 1.

5. A transparent conductive oxide film comprising a rutile metal oxide MO₂, wherein M is selected from the group consisting of Ti, V, Cr, Mo, Ru, and mixtures thereof.

6. The transparent conductive oxide film as claimed in claim 5, further comprising at least one MO₂ film layer, wherein said MO₂ film layer comprises SnO₂ or other metal oxide capable of stabilizing the rutile MO₂ film.

7. The transparent conductive oxide film as claimed in claim 6, comprising a sandwich structure of M′O₂/M″O₂/M″O₂ wherein M′, M″ and M′″ are the same or different.

8. The transparent conductive oxide film as claimed in claim 5, wherein said metal oxide is SnₓM₁₋ₓO₂, where M is selected from the group consisting of Ti, V, Cr, Mo, and Ru.

9. A coated substrate comprising a substrate having directly coated thereon the transparent conductive oxide of claim 5.

10. A transparent conductive oxide film comprising a metal oxide AₓMO_{y} wherein A is selected from the group consisting of H, Li, Na, and K, x=0-2, and M is either W or Mo.

11. A coated substrate comprising a soda lime glass substrate and the transparent conductive oxide film as claimed in claim 10, wherein the metal oxide is deposited on the soda lime glass substrate with consecutive annealing/diffusion of Na, Li and K from the glass, and/or vapor phase with incorporation/implantation of A into AₓMO_{y}.

12. A method of depositing a metal oxide film by atmospheric pressure chemical vapor deposition on a substrate, comprising the step of exposing the heated substrate to a vapor including at least one dopant having an ionic size that approximates a size of host ions in an oxide lattice in the metal oxide.

13. The method as claimed in claim 12, wherein the ionic size of said dopant is between approximately 0.60 Å and 0.80 Å.

14. The method as claimed in claim 12, wherein said metal oxide is selected from the group consisting of Zn²⁺O, Sn⁴⁺O₂, Ge⁴⁺O₂, Zr⁴⁺O₂, Ti⁴⁺O₂, Ga³⁺₂O₃, and mixtures thereof, and wherein said at least one dopant is selected from the group consisting of Sn⁴⁺, Bi⁵⁺, Ta⁵⁺, Hf⁴⁺, Mo⁶⁺, Te⁶⁺, Nb⁵⁺ and mixtures thereof.

15. A method of depositing a metal oxide film by atmospheric pressure chemical vapor deposition on a substrate, comprising the step of exposing the heated substrate to a vapor containing chemical precursors to deposit at least one metal oxide wherein said metal oxide is rutile MO₂, and M is selected from the group consisting of Ti, V, Cr, Mo, Ru and mixtures thereof.

16. The method of claim 15 wherein multiple metal oxide films are deposited by atmospheric pressure chemical vapor deposition, wherein said multiple films comprise M′O₂/M″O₂ bilayers or M′O₂/M″O₂/M′″¹O₂, sandwich structures wherein M′, M″ and M′″ are the same or different, wherein said M′O₂ film layer comprises SnO₂ or other metal oxide capable of stabilizing the rutile MO₂ film.

17. The method of claim 15 wherein said metal oxide is SnₓM₁₋ₓO₂, where M is selected from the group consisting of Ti, V, Cr, Mo, and Ru.

18. A method of depositing metal oxide films by atmospheric pressure chemical vapor deposition on a substrate, comprising the step of exposing the heated substrate to a vapor containing chemical precursors to deposit at least one metal oxide, wherein said metal oxide is AₓMO_{y} wherein A is selected from the group consisting of H, Li, Na, and K, x=0-2, and M is either W or Mo.
